(19) United States
(12) Patent Application Publication
(10) Pub. No.: US 2014/0373899 A1
(43) Pub. Date: Dec. 25, 2014

(54) CONCENTRATOR PHOTOVOLTAIC SYSTEM, METHOD FOR DETECTING TRACKING DEVIATION, METHOD FOR CORRECTING TRACKING DEVIATION, CONTROL DEVICE, PROGRAM FOR DETECTING TRACKING DEVIATION, AND, PROGRAM FOR CORRECTING TRACKING DEVIATION

(71) Applicant: Sumitomo Electric Industries, Ltd., Osaka (JP)

(72) Inventors: Takashi IWASAKI, Osaka (JP); Kenichi HIROTSU, Osaka (JP); Hideaki NAKAHATA, Osaka (JP); Seiji YAMAMOTO, Osaka (JP); Naoki AYAI, Osaka (JP)

(21) Appl. No.: 14/311,880

(22) Filed: Jun. 23, 2014

(30) Foreign Application Priority Data
Apr. 23, 2013 (JP) 2013-090071
Mar. 31, 2014 (JP) 2014-073056
Mar. 31, 2014 (JP) 2014-073286

(51) Int. Cl. G01S 3/786; G01R 21/00; H01L 31/052

(52) U.S. Cl. CPC G01S 3/7861; H01L 31/0522; G01R 21/00
USPC 136/246; 324/76.11

(57) ABSTRACT

Provided is a concentrator photovoltaic system including: a concentrator photovoltaic panel; a driving device configured to cause the concentrator photovoltaic panel to perform operation of tracking the sun; and a control device configured to detect a change pattern repeatedly occurring in temporal change in generated power of the concentrator photovoltaic panel, and configured to compare the detected change pattern with a form characteristic to deviation in an azimuth and a form characteristic to deviation in an elevation, to detect the presence/absence of deviation in tracking.

### TECHNICAL FIELD

The present invention relates to a concentrator photovoltaic (CPV) for generating power by concentrating sunlight on a power generating element.

### BACKGROUND ART

Concentrator photovoltaic is based on a structure in which sunlight concentrated by a lens is caused to be incident on a power generating element (solar cell) formed by a small-sized compound semiconductor having a high power generating efficiency. Specifically, for example, a plurality of insulating substrates such as ceramics with wiring, each insulating substrate having one power generating element mounted thereon, are arranged at light-concentrating positions, and power generated on each insulating substrate is collected by an electric wire (for example, see NON PATENT LITERATURE 1).

When such a basic structure is used as a concentrator photovoltaic module, by further arranging a plurality of the modules, a concentrator photovoltaic panel is formed. Then, a driving device causes the entirety of the concentrator photovoltaic panel to perform tracking operation so as to always face the sun, whereby a desired generated power can be obtained. Basically, the tracking operation relies on a tracking sensor and estimation of the position of the sun based on the time, the latitude, and the longitude of the installation place. There has also been proposed that installation error of the equipment is absorbed by use of software (for example, see Patent Literature 1).

### CITATION LIST

### Patent Literature

PATENT LITERATURE 1: Japanese Laid-Open Patent Publication No. 2009-186094

### Non Patent Literature

NON PATENT LITERATURE 1: “Failure Modes of CPV Modules and How to Test for Them”, [online], Feb. 19, 2010, Emcore Corporation, [Retrieved on Mar. 7, 2013] Internet <URL: http://www1.eere.energy.gov/solar/pdfs/pvrw2010_aeby.pdf#search=‘emcore Pointfocus Fresnel Lens HCPV System’>

### SUMMARY OF INVENTION

### Technical Problem

However, the tracking sensor cannot be said as being completely free of errors, and may have tracking deviation. Also, due to a long-term use, distortion occurring on the concentrator photovoltaic panel or the pedestal which supports the concentrator photovoltaic panel may cause tracking deviation.

Meanwhile, even when slight tracking deviation is occurring, as long as the deviation is not so large as to cause concentrated sunlight to be completely outside the power generating element, generated power can be obtained. Thus, occurrence of tracking deviation itself is difficult to be found. Moreover, no technology has yet been proposed that determines the manner of the deviation.

In view of the above problems, an object of the present invention is to provide a technology of finding at least deviation in tracking the sun in concentrator photovoltaic.

### Solution to Problem

A concentrator photovoltaic system of the present invention includes: a concentrator photovoltaic panel; a driving device configured to cause the concentrator photovoltaic panel to perform operation of tracking the sun; and a control device configured to detect a change pattern repeatedly occurring in temporal change in generated power of the concentrator photovoltaic panel, and configured to compare the detected change pattern with a form characteristic to deviation in an azimuth and a form characteristic to deviation in an elevation, to detect the presence/absence of deviation in tracking.

In the above concentrator photovoltaic system, based on the finding that information regarding deviation in tracking is included in a change pattern repeatedly occurring in temporal change in generated power, the detected change pattern is compared with a form characteristic to deviation in the azimuth and a form characteristic to deviation in the elevation, whereby the presence/absence of deviation in tracking can be detected. Therefore, from the temporal change in generated power, deviation in tracking the sun can be found.

Moreover, the present invention is a method for detecting tracking deviation in a concentrator photovoltaic apparatus including a driving device configured to cause a concentrator photovoltaic panel to perform operation of tracking the sun, the method including: detecting a change pattern included in temporal change in generated power of the concentrator photovoltaic panel; and comparing the detected change pattern with a form characteristic to deviation in an azimuth and a form characteristic to deviation in an elevation, to detect the presence/absence of deviation in tracking.

In the above method for detecting tracking deviation, based on the finding that information regarding deviation in tracking is included in a change pattern repeatedly occurring in temporal change in generated power, the detected change pattern is compared with a form characteristic to deviation in the azimuth and a form characteristic to deviation in the elevation, whereby the presence/absence of deviation in tracking can be detected. Therefore, from the temporal change in generated power, deviation in tracking the sun can be found.

Moreover, the present invention is a method for correcting tracking deviation, the method being executed, in a concentrator photovoltaic apparatus including a driving device configured to cause a concentrator photovoltaic panel to perform operation of tracking the sun, by a control device configured to detect generated power of the concentrator photovoltaic panel and to control the driving device, the method including: detecting a change pattern included in temporal change in generated power of the concentrator photovoltaic panel; comparing the detected change pattern with a form characteristic to deviation in an azimuth and a form characteristic to deviation in an elevation, to detect the presence/absence of deviation in tracking; identifying, when the deviation is present, among two axes of the azimuth and the elevation, an axis in which the deviation is occurring; and instructing the driving device to correct an angle in the identified axis.

In the above method for correcting tracking deviation, based on the finding that information regarding deviation in tracking is included in a change pattern repeatedly occurring in temporal change in generated power, the detected change pattern is compared with a form characteristic to deviation in the azimuth and a form characteristic to deviation in the elevation. As a result of the comparison, when there is no indication of tracking deviation in the change pattern, the tracking is being performed normally. As a result of the comparison, when the deviation is present, based on similarity of the form of the change pattern, among two axes of the azimuth and the elevation, an axis in which the deviation is occurring is identified, and the driving device is instructed to correct an angle in the identified axis. Accordingly, the deviation is accurately corrected. Therefore, it is possible to provide a technology of finding, from the temporal change in generated power, deviation in tracking the sun and eliminating this deviation.

Other than the above, the present invention is a control device configured to be used in a concentrator photovoltaic system, the concentrator photovoltaic system including a concentrator photovoltaic panel and a driving device configured to cause the concentrator photovoltaic panel to perform operation of tracking the sun, the control device having a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking.

Moreover, the present invention is a program for detecting tracking deviation to be used in a concentrator photovoltaic system, the concentrator photovoltaic system including a concentrator photovoltaic panel and a driving device configured to cause the concentrator photovoltaic panel to perform operation of tracking the sun, the program causing a computer to realize a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking.

Moreover, the present invention is a program for correcting tracking deviation to be used in a concentrator photovoltaic system, the concentrator photovoltaic system including a concentrator photovoltaic panel and a driving device configured to cause the concentrator photovoltaic panel to perform operation of tracking the sun, the program causing a computer to realize: a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking; and a function of, when the deviation in tracking is present, identifying, among two axes of the azimuth and the elevation, an axis in which the deviation is occurring, and instructing the driving device to correct an angle in the identified axis.

### Advantageous Effects of Invention

According to the concentrator photovoltaic system and the method for detecting tracking deviation of the present invention, from the change pattern in generated power of the concentrator photovoltaic, deviation in tracking the sun can be found.

### BRIEF DESCRIPTION OF DRAWINGS

FIG. 1 is a perspective view showing one example of a concentrator photovoltaic apparatus.

FIG. 2 is a perspective view (partially cut out) showing an enlarged view of one example of a concentrator photovoltaic module.

FIG. 3 is an enlarged view of a III portion in FIG. 2.

FIG. 4 is a perspective view showing a state where, by using, as “one unit”, the concentrator photovoltaic apparatus formed by arranging 64 (8 in length×8 in breadth) modules each having a substantially square shape, 15 units are arranged in the premises.

FIG. 5 shows graphs of measured values of generated power of the 15 units of concentrator photovoltaic apparatuses at a time zone (11 o'clock to 12 o'clock) around the culmination time of the sun on one day.

FIG. 6 shows four graphs representing extracted characteristic change patterns of waveforms.

FIG. 7 shows a graph of pattern (a) and perspective charts each showing a position where a concentration spot is formed on a power generating element.

FIG. 8 shows a graph of pattern (b) and perspective charts each showing a position where the concentration spot is formed on the power generating element.

FIG. 9 shows a graph of pattern (c) and perspective charts each showing a position where the concentration spot is formed on the power generating element.

FIG. 10 shows a graph of pattern (d) and perspective charts each showing a position where the concentration spot is formed on the power generating element.

FIG. 11 is a graph of examination, with respect to one module, for example, of how generated power is reduced in a period from when tracking is stopped around the culmination time where the elevation scarcely changes till tracking is resumed.

FIG. 12 shows an example of correction of the elevation.

FIG. 13 shows one example of a concentrator photovoltaic system viewed in terms of tracking operation.

FIG. 14 is a flow chart (1/2) showing a process regarding detection and correction of tracking deviation, to be executed by a control device.

FIG. 15 is a flow chart (2/2) showing the process regarding detection and correction of tracking deviation, to be executed by the control device.

FIG. 16 shows another example of the concentrator photovoltaic system viewed in terms of tracking operation.

FIG. 17 shows another example of the concentrator photovoltaic system.

FIG. 18 shows another example of the concentrator photovoltaic system.

FIG. 19 shows another example of the concentrator photovoltaic system.

### DESCRIPTION OF EMBODIMENTS

### Summary of Embodiment

The summary of the embodiment of the present invention includes at least the following.

(1) This concentrator photovoltaic system includes: a concentrator photovoltaic panel; a driving device configured to cause the concentrator photovoltaic panel to perform operation of tracking the sun; and a control device configured to detect a change pattern repeatedly occurring in temporal change in generated power of the concentrator photovoltaic panel, and configured to compare the detected change pattern with a form characteristic to deviation in an azimuth and a form characteristic to deviation in an elevation, to detect the presence/absence of deviation in tracking.

In the above concentrator photovoltaic system, based on the finding that information regarding deviation in tracking is included in a change pattern repeatedly occurring in temporal change in generated power, the detected change pattern is compared with a form characteristic to deviation in the azimuth and a form characteristic to deviation in the elevation, whereby the presence/absence of deviation in tracking can be detected. Therefore, from the temporal change in generated power, deviation in tracking the sun can be found.

(2) Moreover, in the concentrator photovoltaic system of (1) above, when the deviation in tracking is present, the control device may identify, among two axes of the azimuth and the elevation, an axis in which the deviation is occurring, and may instruct the driving device to correct an angle in the identified axis.

In this case, by identifying the axis in which the deviation is occurring, and by instructing the driving device to correct an angle in the identified axis, the deviation is accurately corrected. Thus, it is possible to provide a technology of finding, from the temporal change in generated power, deviation in tracking the sun and eliminating this deviation.

(3) Moreover, in the concentrator photovoltaic system of (2) above, the control device may determine a sign of the angle to be corrected, based on whether a sawtooth-like change pattern included in the change pattern is

(a) a pattern increasing gradually and decreasing at a time of stepped change, or

(b) a pattern decreasing gradually and increasing at a time of stepped change.

In this case, it is possible to appropriately determine whether to correct the angle in a plus direction or a minus direction.

(4) Moreover, in the concentrator photovoltaic system of (2) or (3) above, the control device may determine an absolute value of the angle to be corrected, based on generated power reduced relative to generated power without deviation, stored in advance.

In this case, for example, by intentionally causing deviation, the relationship between the deviation and reduction of generated power can be accurately understood in advance. Moreover, this technique can be applied to a change pattern of either azimuth deviation or elevation deviation.

(5) Moreover, in the concentrator photovoltaic system of (2) or (3) above, the control device may determine an absolute value of the angle to be corrected, based on a change ratio of generated power corresponding to tracking operation.

In this case, it is possible to accurately understand in advance the relationship between the deviation and the change ratio of generated power. Moreover, application to a change pattern of either azimuth deviation or elevation deviation is allowed. Further, application to a change pattern in which azimuth deviation and elevation deviation are mixed is also preferably allowed.

(6) Moreover, in the concentrator photovoltaic system of any of (2) to (5) above, the concentrator photovoltaic panel may include a pyrheliometer, and only when a direct solar irradiance detected by the pyrheliometer is not less than a predetermined value, the control device may perform the correction.

In this case, correction is performed when the sky is clear where solar radiation is stable, and thus, influence of clouds on direct solar irradiance can be eliminated.

(7) Moreover, in the concentrator photovoltaic system of any of (2) to (6) above, the control device may perform the correction in a time zone where the sun culminates.

In this case, the elevation is stable and shows a substantially constant value, and thus, detection of a change pattern based on deviation in the azimuth is easy.

(8) Moreover, in the concentrator photovoltaic system of any of (2) to (5) above, as a pyranometer, a normal pyranometer or a horizontal pyranometer may be provided, and in a case of the normal pyranometer, when a normal global solar irradiance detected by the normal pyranometer is not less than a predetermined value, the correction may be performed, and in a case of the horizontal pyranometer, only when a horizontal global solar irradiance detected by the horizontal pyranometer is not less than a predetermined value, the correction may be performed.

In this case, compared with the pyrheliometer, the normal pyranometer or the horizontal pyranometer is less likely to be affected by dirt on a window portion of a built-in solar radiation sensor. Moreover, the normal pyranometer or the horizontal pyranometer has fewer problems of tracking deviation causing measurement error in the case of the pyrheliometer. Thus, with regard to actual intensity measurement of sunlight, there are cases where more accurate information can be obtained.

(9) Moreover, the concentrator photovoltaic system of any of (2) to (8) above may further include a communication device configured to transmit a measurement signal of an electric power meter measuring the generated power, and configured to receive a correction signal to the driving device, wherein the control device may be installed in a place distanced from the concentrator photovoltaic panel and the driving device, and may perform communication with the communication device via a communication line to receive the measurement signal and transmit the correction signal.

In this case, deviation in tracking can be corrected by remote control via the communication line, and thus, the configuration is preferable for centralized management from a distant place.

(10) On the other hand, when viewed in terms of a method for detecting tracking deviation, this is a method for detecting tracking deviation in a concentrator photovoltaic apparatus including a driving device configured to cause a concentrator photovoltaic panel to perform operation of tracking the sun, the method including: detecting a change pattern included in temporal change in generated power of the concentrator photovoltaic panel; and comparing the detected change pattern with a form characteristic to deviation in an azimuth and a form characteristic to deviation in an elevation, to detect the presence/absence of deviation in tracking.

In the method for detecting tracking deviation above, based on the finding that information regarding deviation in tracking is included in a change pattern repeatedly occurring in temporal change in generated power, the detected change pattern is compared with a form characteristic to deviation in the azimuth and a form characteristic to deviation in the elevation, whereby the presence/absence of deviation in tracking can be detected. Therefore, from the temporal change in generated power, deviation in tracking the sun can be found.

(11) Moreover, when viewed in terms of a method for correcting tracking deviation, this is a method for correcting tracking deviation, the method being executed, in a concentrator photovoltaic apparatus including a driving device configured to cause a concentrator photovoltaic panel to perform operation of tracking the sun, by a control device configured to detect generated power of the concentrator photovoltaic panel and to control the driving device, the method including: detecting a change pattern included in temporal change in generated power of the concentrator photovoltaic panel; comparing the detected change pattern with a form characteristic to deviation in an azimuth and a form characteristic to deviation in an elevation, to detect the presence/absence of deviation in tracking; identifying, when the deviation is present, among two axes of the azimuth and the elevation, an axis in which the deviation is occurring; and instructing the driving device to correct an angle in the identified axis.

In the method for correcting tracking deviation above, based on the finding that information regarding deviation in tracking is included in a change pattern repeatedly occurring in temporal change in generated power, the detected change pattern is compared with a form characteristic to deviation in the azimuth and a form characteristic to deviation in the elevation. As a result of the comparison, when there is no indication of tracking deviation in the change pattern, the tracking is being performed normally. As a result of the comparison, when the deviation is present, based on similarity of the form of the change pattern, among two axes of the azimuth and the elevation, an axis in which the deviation is occurring is identified, and the driving device is instructed to correct an angle in the identified axis. Accordingly, the deviation is accurately corrected. Therefore, it is possible to provide a technology of finding, from the temporal change in generated power, deviation in tracking the sun and eliminating this deviation.

(12) Moreover, in the method for correcting tracking deviation of (11) above, by measuring temporal change in generated power with either one of the azimuth and the elevation fixed, deviation in the other angle corresponding to generated power reduced relative to generated power without deviation may be examined, in advance.

In this case, by forcedly creating tracking deviation, deviation in the angle corresponding to the reduced generated power can be easily examined.

(13) Moreover, this is a control device configured to be used in a concentrator photovoltaic system, the concentrator photovoltaic system including a concentrator photovoltaic panel and a driving device configured to cause the concentrator photovoltaic panel to perform operation of tracking the sun, the control device having a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking.

In the control device above, based on the finding that information regarding deviation in tracking is included in a change pattern repeatedly occurring in temporal change in generated power, the detected change pattern is compared with a form characteristic to deviation in the azimuth and a form characteristic to deviation in the elevation, whereby the presence/absence of deviation in tracking can be detected. Therefore, from the temporal change in generated power, deviation in tracking the sun can be found.

(14) Moreover, the control device of (13) above may have a function of identifying, when the deviation in tracking is present, among two axes of the azimuth and the elevation, an axis in which the deviation is occurring, and instructing the driving device to correct an angle in the identified axis.

In this case, by identifying the axis in which the deviation is occurring, and by instructing the driving device to correct an angle in the identified axis, the deviation is accurately corrected. Thus, it is possible to provide a technology of finding, from the temporal change in generated power, deviation in tracking the sun and eliminating this deviation.

(15) Moreover, the control device of (13) or (14) above, the function may be realized by a semiconductor integrated circuit.

In this case, necessary functions are installed as a semiconductor integrated circuit in one-chip IC, for example, and thus, production of the concentrator photovoltaic system can be facilitated. Moreover, the semiconductor integrated circuit can be produced at a low cost.

(16) Moreover, this is a program for detecting tracking deviation to be used in a concentrator photovoltaic system, the concentrator photovoltaic system including a concentrator photovoltaic panel and a driving device configured to cause the concentrator photovoltaic panel to perform operation of tracking the sun, the program causing a computer to realize a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking.

In the program for detecting tracking deviation above, based on the finding that information regarding deviation in tracking is included in a change pattern repeatedly occurring in temporal change in generated power, the detected change pattern is compared with a form characteristic to deviation in the azimuth and a form characteristic to deviation in the elevation, whereby the presence/absence of deviation in tracking can be detected. Therefore, from the temporal change in generated power, deviation in tracking the sun can be found. Further, since necessary functions are put into programs, production of the concentrator photovoltaic system is easy, addition to an existing concentrator photovoltaic system is also easy, and version up of the system is also easy.

(17) Moreover, this is a program for correcting tracking deviation to be used in a concentrator photovoltaic system, the concentrator photovoltaic system including a concentrator photovoltaic panel and a driving device configured to cause the concentrator photovoltaic panel to perform operation of tracking the sun, the program causing a computer to realize: a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking; and a function of, when the deviation in tracking is present, identifying, among two axes of the azimuth and the elevation, an axis in which the deviation is occurring, and instructing the driving device to correct an angle in the identified axis.

In the program for correcting tracking deviation above, based on the finding that information regarding deviation in tracking is included in a change pattern repeatedly occurring in temporal change in generated power, the detected change pattern is compared with a form characteristic to deviation in the azimuth and a form characteristic to deviation in the elevation. As a result of the comparison, when there is no indication of tracking deviation in the change pattern, the tracking is being performed normally. As a result of the comparison, when the deviation is present, based on similarity of the form of the change pattern, among two axes of the azimuth and the elevation, an axis in which the deviation is occurring is identified, and the driving device is instructed to correct an angle in the identified axis. Accordingly, the deviation is accurately corrected. Therefore, it is possible to provide a technology of finding, from the temporal change in generated power, deviation in tracking the sun and eliminating this deviation. Further, since necessary functions are put into programs, production of the concentrator photovoltaic system is easy, addition to an existing concentrator photovoltaic system is also easy, and version up of the system is also easy.

It should be noted that the programs of (16) and (17) can be stored in a computer-readable storage medium.

In this case, the programs are stored in the storage medium and can be distributed as a storage medium.

### Details of Embodiments

### One Example of Concentrator Photovoltaic Apparatus

Hereinafter, details of embodiments of the present invention will be described with reference to the drawings. First, a structure of a concentrator photovoltaic apparatus will be described.

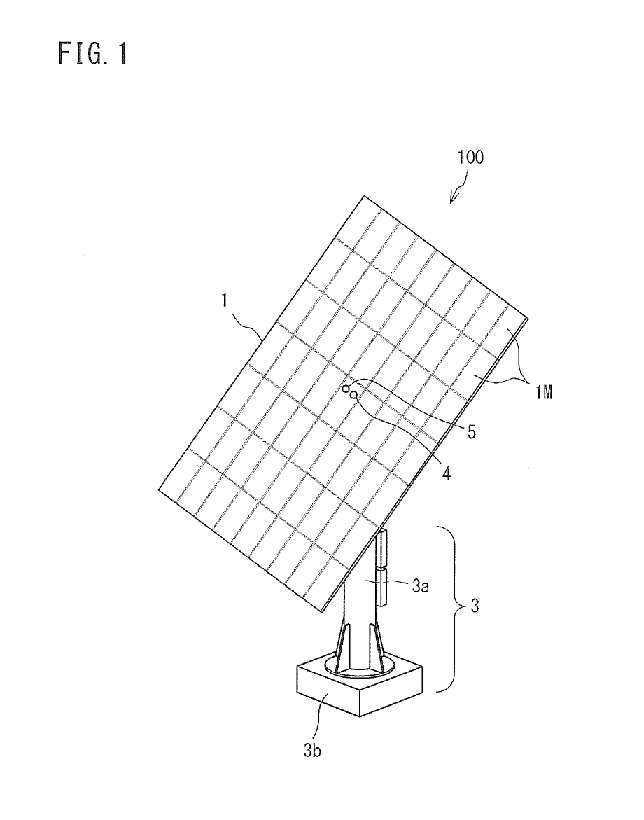

FIG. 1 is a perspective view showing one example of a concentrator photovoltaic apparatus. In the drawing, a concentrator photovoltaic apparatus 100 includes a concentrator photovoltaic panel 1, and a pedestal 3 which includes a post 3a and a base 3b thereof, the post 3a supporting the concentrator photovoltaic panel 1 on the rear surface thereof. The concentrator photovoltaic panel 1 is formed by assembling multiple concentrator photovoltaic modules 1M vertically and horizontally. In this example, 62 (7 in length×9 in breadth−1) concentrator photovoltaic modules 1M are assembled vertically and horizontally, except the center portion. When one concentrator photovoltaic module 1M has a rated output of, for example, about 100 W, the entirety of the concentrator photovoltaic panel 1 has a rated output of about 6 kW.

On the rear surface side of the concentrator photovoltaic panel 1, a driving device (not shown) is provided, and by operating the driving device, it is possible to drive the concentrator photovoltaic panel 1 in two axes of the azimuth and the elevation. Accordingly, the concentrator photovoltaic panel 1 is driven so as to always face the direction of the sun in both of the azimuth and the elevation, by use of stepping motors (not shown). At a place (in this example, the center portion) on the concentrator photovoltaic panel 1, or in the vicinity of the panel 1, a tracking sensor 4 and a pyrheliometer 5 are provided. Operation of tracking the sun is performed, relying on the tracking sensor 4 and the position of the sun calculated from the time, the latitude, and the longitude of the installation place.

That is, every time the sun has moved by a predetermined angle, the driving device drives the concentrator photovoltaic panel 1 by the predetermined angle. The event that the sun has moved by the predetermined angle may be determined by the tracking sensor 4, or may be determined by the latitude, the longitude, and the time. Thus, there are also cases that the tracking sensor 4 is omitted. The predetermined angle is, for example, a constant value, but the value may be changed in accordance with the altitude of the sun and the time. Moreover, use of the stepping motors is one example, and other than this, a drive source capable of performing precise operation may be used.

<<One Example of Concentrator Photovoltaic Module>>

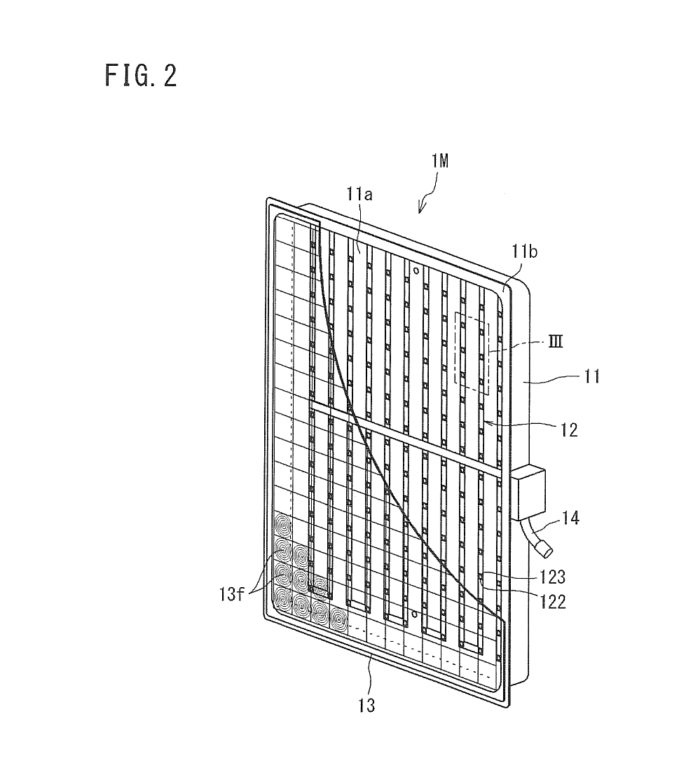

FIG. 2 is a perspective view (partially cut out) showing an enlarged view of one example of the concentrator photovoltaic module (hereinafter, also simply referred to as module) 1M. In the drawing, the module 1M includes, as main components, a housing 11 formed in a vessel shape (vat shape) and having a bottom surface 11a, a flexible printed circuit 12 provided in contact with the bottom surface 11a, and a primary concentrating portion 13 attached, like a cover, to a flange portion 11b of the housing 11. The housing 11 is made of metal.

The primary concentrating portion 13 is a Fresnel lens array and is formed by arranging, in a matrix shape, a plurality of (for example, 16 in length×12 in breadth, 192) Fresnel lenses 13f as lens elements which concentrate sunlight. The primary concentrating portion 13 can be obtained by, for example, forming a silicone resin film on a back surface (inside) of a glass plate used as a base material. Each Fresnel lens is formed on this resin film. On the external surface of the housing 11, a connector 14 for taking out an output from the module 1M is provided.

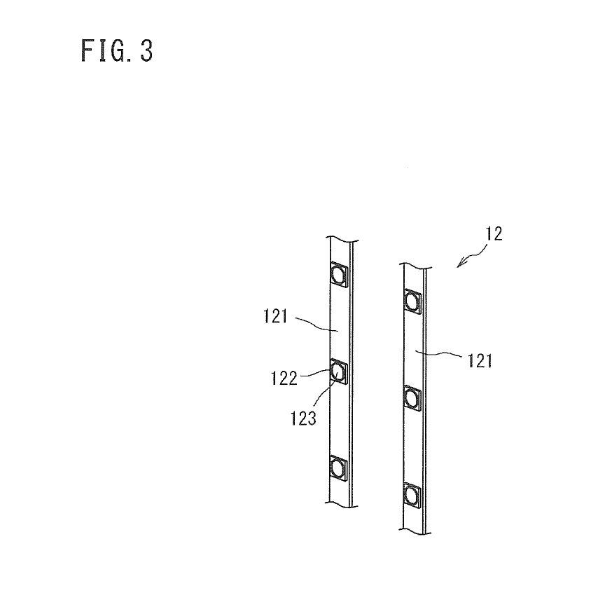

FIG. 3 is an enlarged view of a III portion in FIG. 2. In FIG. 3, the flexible printed circuit 12 includes a flexible substrate 121 having a ribbon shape, power generating elements (solar cells) 122 provided thereon, and secondary concentrating portions 123 respectively provided so as to cover the power generating elements 122. Sets of the power generating element 122 and the secondary concentrating portion 123 are provided at positions corresponding to the Fresnel lenses 13f of the primary concentrating portion 13, by the same number of the Fresnel lenses 13f. The secondary concentrating portion 123 concentrates sunlight incident from a corresponding Fresnel lens 13f onto the power generating element 122. The secondary concentrating portion 123 is a lens, for example. However, the secondary concentrating portion 123 may be a reflecting mirror that guides light downwardly while reflecting the light. Further, there is also a case where a secondary concentrating portion is not used. The power generating elements 122 are electrically connected in series-parallel by the flexible printed circuit 12, and the collected generated power is taken out through the connector 14 (FIG. 2).

It should be noted that the module 1M shown in FIG. 2 and FIG. 3 is merely one example, and there could be other various configurations of the module. For example, not the flexible printed substrate as above but multiple resin substrates or multiple ceramic substrates having a flat plate shape (rectangular shape or the like) may be used.

<<Installation Example of a Plurality of Units of Concentrator Photovoltaic Apparatuses>>

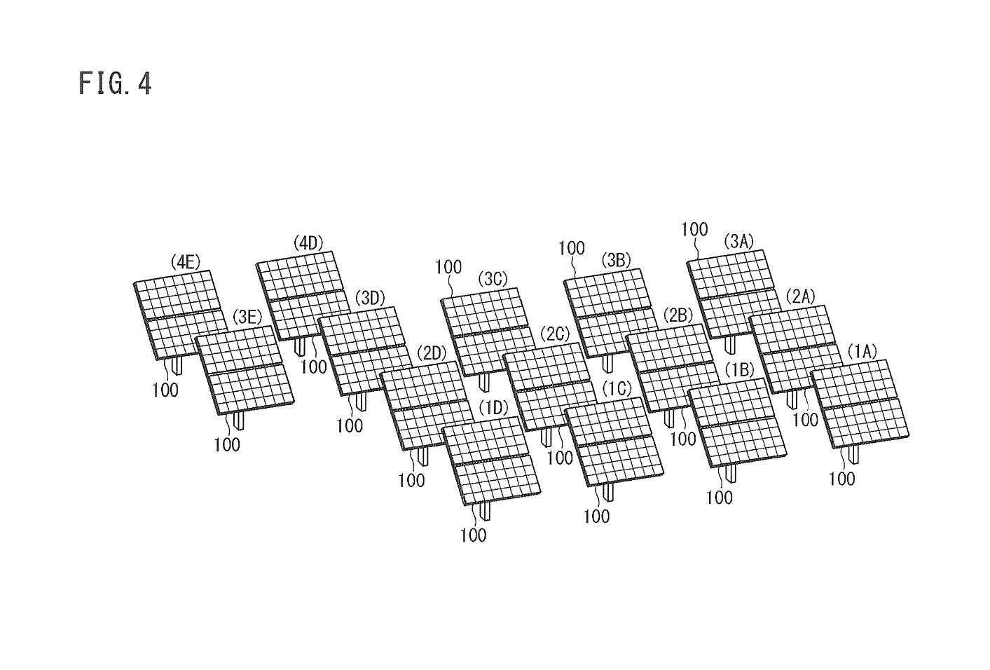

With regard to the concentrator photovoltaic apparatus 100 configured as above, the panel configuration (the number and arrangement of the modules 1M) can be freely changed as necessary. Also, the shape of the module can be rectangular, square, or a shape other than these. For example, FIG. 4 is a perspective view showing a state where, when the concentrator photovoltaic apparatus 100 formed by arranging 64 (8 in length×8 in breadth) modules each having a substantially square shape is defined as “one unit”, 15 units are arranged in the premises. Each unit is driven by its corresponding driving device (not shown) so as to track the sun. Here, 15 units of the concentrator photovoltaic apparatus 100 will be denoted by the following reference characters (also shown in FIG. 4) for convenience.

Four units in the front row: 1A, 1B, 1C, and 1D

Four units in the second row: 2A, 2B, 2C, and 2D

Five units in the third row: 3A, 3B, 3C, 3D, and 3E

Two units in the fourth row: 4D and 4E

<<Example of Temporal Change in Generated Power>>

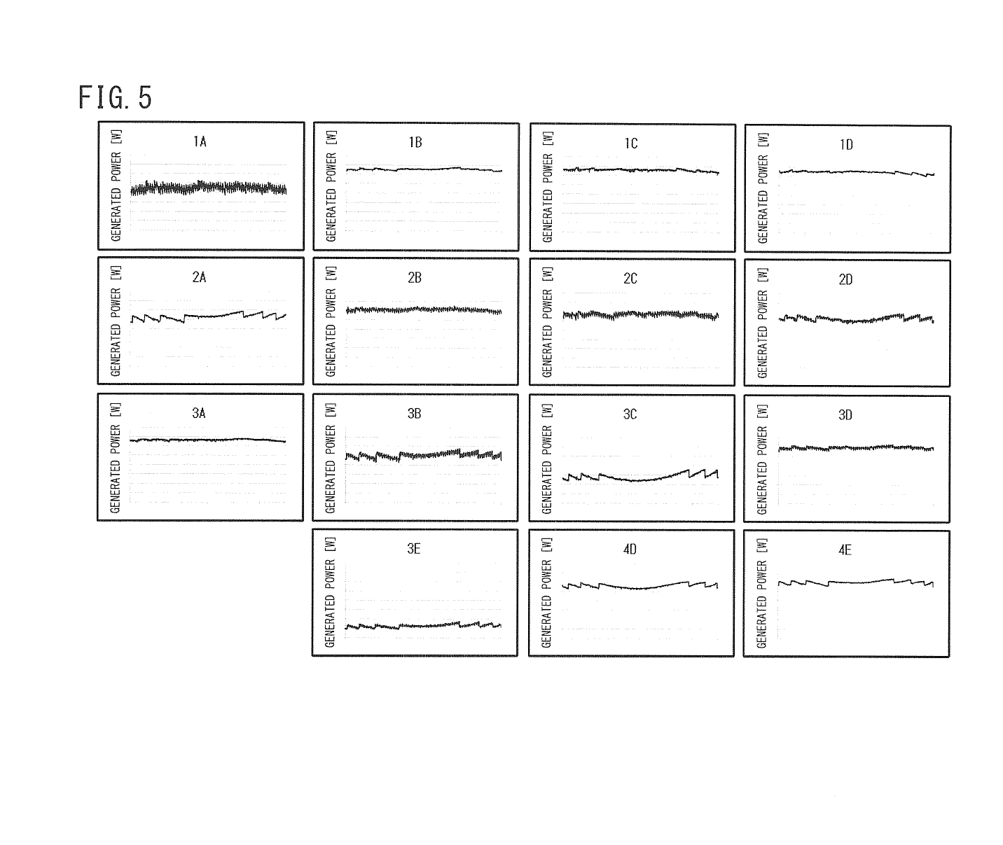

FIG. 5 shows graphs of measured values of generated power of the 15 units of the concentrator photovoltaic apparatus 100 (1A to 4E) in a time zone (11 o'clock to 12 o'clock) around the culmination time of the sun on one day. In each graph, the horizontal axis represents time, and the vertical axis represents electric power. What to be focused on here is not the differences in generated powers among the units, but the characteristics of change included in each waveform.

Specifically, many waveforms include sawtooth-like stepped portions (jaggy portions) showing mechanical changes, and there observed are two types of change, i.e., change repeated in a short cycle, and change repeated in a relatively long cycle. The cause of the change is deviation in tracking. That is, when there is no deviation in tracking, no large change occurs in generated power before and after operation (tracking operation) of the stepping motor, but when there is deviation in tracking, a large change is caused in generated power before and after operation of the stepping motor. Thus, it is considered that the trace of the operation of the stepping motor appears as a relatively large change in generated power. Since each graph is of the time around the culmination time, there is least change in the elevation in the day. Therefore, the longer cycle (2-5 minute cycle) is caused by deviation in tracking in the elevation. The shorter cycle (20-60 second cycle) is caused by deviation in tracking in the azimuth.

<<Examples of Characteristic Change Patterns>>

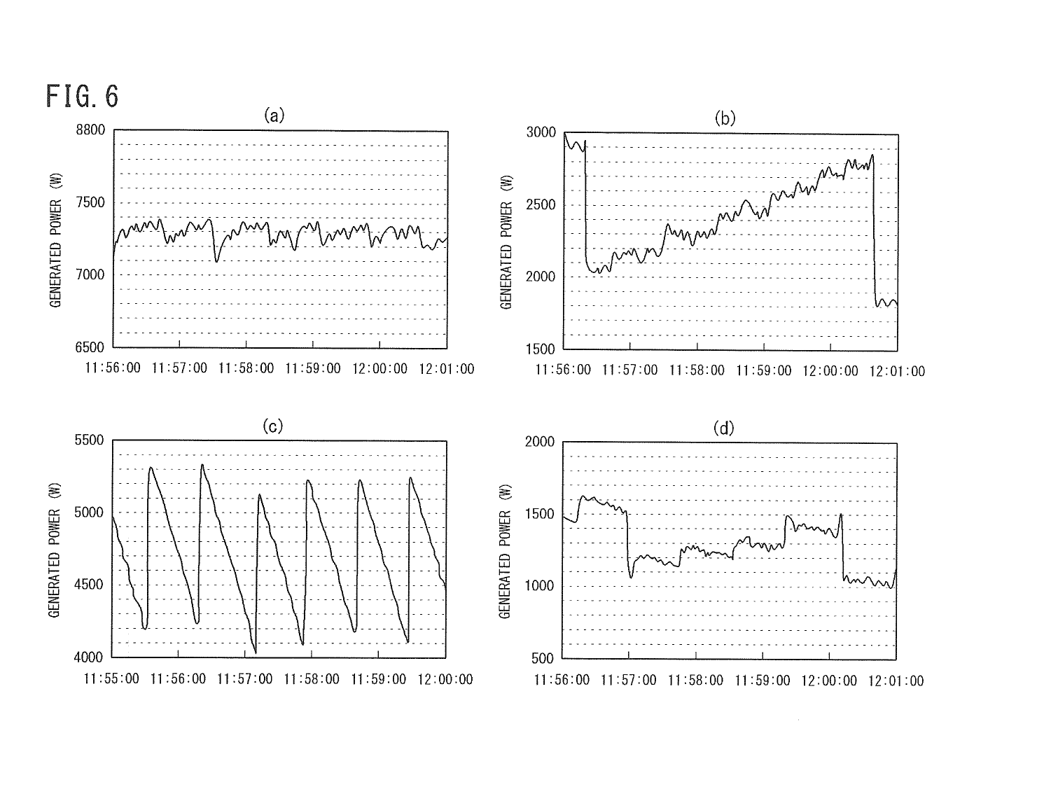

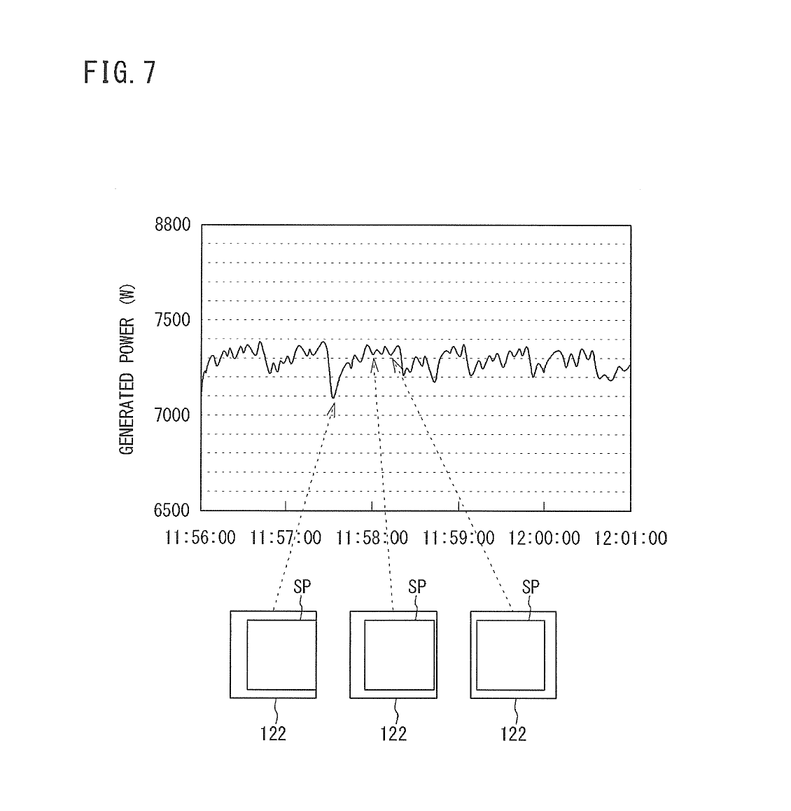

FIG. 6 shows four graphs representing extracted characteristic change patterns of waveforms. In each graph, the horizontal axis represents time and the vertical axis represents generated power. In pattern (a) at the upper left, the magnitude of change of generated power is as small as about 300 W (about 4% of the entirety) at maximum, and thus, the deviation in tracking is small enough to be allowed, and thus, this is a stable state in which good tracking operation is being performed. FIG. 7 shows the graph of the pattern (a) in FIG. 6 and perspective charts each showing a position where a concentration spot SP is formed on the power generating element 122. In addition, broken lines show relationship between the positions on the graph and the perspective charts. As shown, the concentration spot SP is slightly off the power generating element 122 in the perspective chart at the left end, but this is a substantially good state as a whole. That is, in such a case, there is no deviation in tracking, and thus there is no need to perform correction.

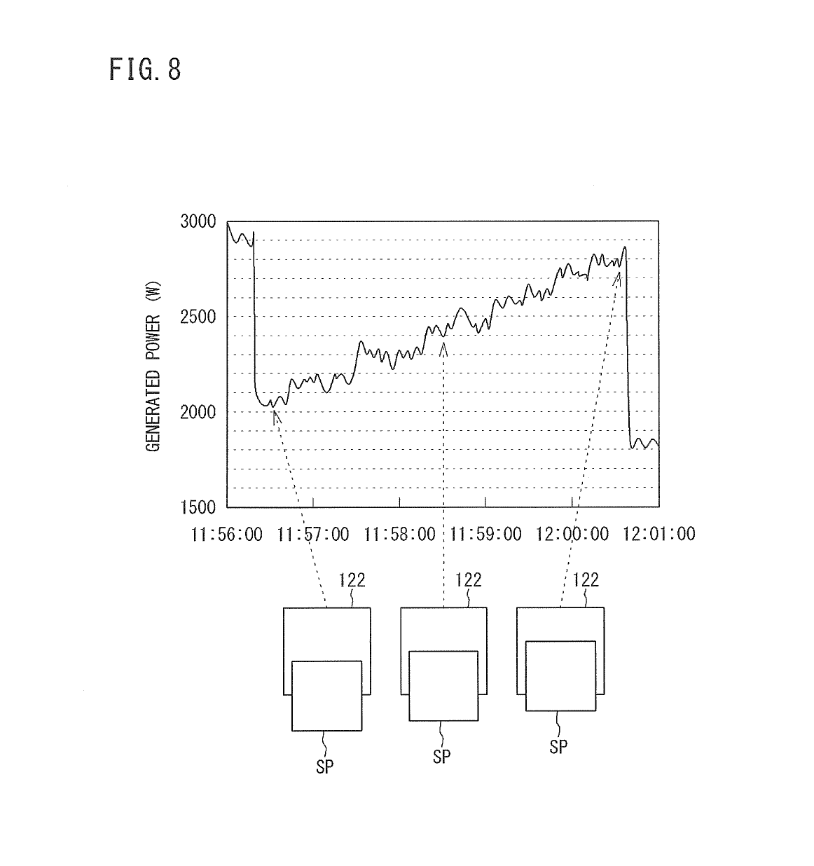

With reference back to FIG. 6, in pattern (b) at the upper right, between 11 o'clock 56 minutes and 11 o'clock 57 minutes, and between 12 o'clock 0 minutes and 12 o'clock 1 minute, large changes are occurring, and this is repeated in a long cycle of about four minutes. This is a trace of operation of the stepping motor with deviation occurring in tracking in the elevation. FIG. 8 shows the graph of the pattern (b) in FIG. 6 and perspective charts each showing a position where the concentration spot SP is formed on the power generating element 122. In addition, broken lines show relationship between the positions on the graph and the perspective charts. As shown, in the perspective chart at the left end, the concentration spot SP is greatly off the power generating element 122. Thereafter, the concentration spot SP gradually enters the area of the power generating element 122, but upon operation of the stepping motor, the concentration spot SP comes to be greatly off again. Then, this is repeated. Therefore, in such a case, it is necessary to correct deviation in tracking in the elevation. Moreover, in this case, the change pattern is composed of repetition of large changes, and small changes therebetween. Between a large change and the next large change, generated power shows an increasing tendency, and at the operation of the stepping motor, the change in generated power shows a decrease. Such a change pattern indicates that angle deviation is in an advancing direction. It should be noted that the magnitude of the small changes is as small as about 200 W (not higher than 10% of the entirety) at maximum, and the small changes can be regarded as fluctuation components, and thus the small changes are not the target for correction.

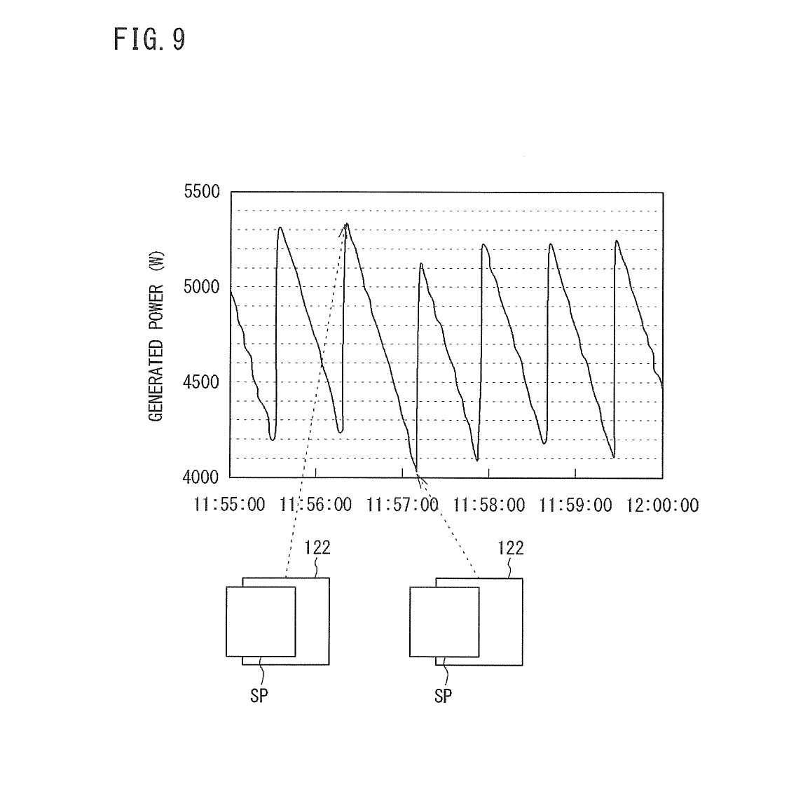

With reference back to FIG. 6, pattern (c) at the lower left, large changes are occurring in a 20-30 second cycle. This is a trace of operation of the stepping motor with deviation occurring in tracking in the azimuth. FIG. 9 shows the graph of the pattern (c) in FIG. 6 and perspective charts each showing a position where the concentration spot SP is formed on the power generating element 122. In addition, broken lines show relationship between the positions on the graph and the perspective charts. The perspective chart on the left side shows a state immediately after operation of the stepping motor, and the concentration spot SP is relatively well enough in the area of the power generating element 122. From this point, in accordance with movement of the sun in the azimuth, generated power gradually decreases, resulting in the state of the perspective chart on the right side, and, again, the stepping motor operates. Then, this is repeated. Therefore, in such a case, it is necessary to correct deviation in tracking in the azimuth. Moreover, in this case, the change having a substantially constant slope between large changes shows a decreasing tendency, and at the operation of the stepping motor, the change in generated power shows an increase. Such a change pattern indicates that the angle deviation is in a delay direction.

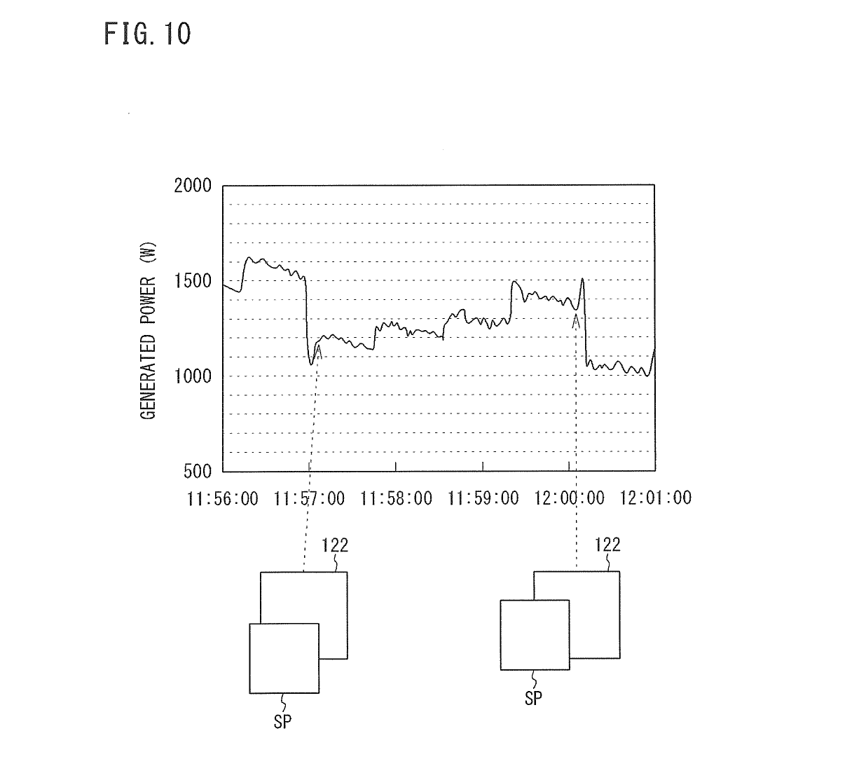

With reference back to FIG. 6, pattern (d) at the lower right is a mixed type of the patterns (b) and (c). That is, here, deviation is occurring both in tracking in the azimuth and tracking in the elevation. FIG. 10 shows the graph of the pattern (d) in FIG. 6 and perspective charts each showing a position where the concentration spot SP is formed on the power generating element 122. In addition, broken lines show relationship between the positions on the graph and the perspective charts. As shown, in both the perspective chart on the left side and the perspective chart on the right side, the concentration spot SP is relatively greatly off the area of the power generating element 122 (however, in the right perspective chart, the degree of being off is slightly smaller). Therefore, in such a case, it is necessary to correct deviation in tracking in the azimuth and deviation in tracking in the elevation. Between the large change around 11 o'clock 57 minutes and the next large change around 12 o'clock 10 seconds, generated power shows an increasing tendency as a whole, and the change at operation of the stepping motor corresponding to each large change shows a decrease. This occurs in a long cycle of about three minutes. Moreover, between medium changes occurring at around 11 o'clock 56 minutes 15 seconds, around 11 o'clock 57 minutes 02 seconds, around 11 o'clock 57 minutes 48 seconds, around 11 o'clock 58 minutes 34 seconds, and around 11 o'clock 59 minutes 20 seconds, generated power shows a decreasing tendency and the change at operation of the stepping motor corresponding to each medium change shows an increase. The medium change occurs in an about 46-second cycle. The former corresponds to deviation in the elevation, and the latter corresponds to deviation in the azimuth. In such a case, a method may be employed in which one deviation angle is corrected first, and then the procedure is returned to the start point thereof, or a method may be employed in which before returning to the start point, the deviation angle in the other axis is subsequently corrected. It should be noted that small changes whose change amount is less than 100 W (not higher than 10% of the entirety) can be regarded as fluctuation components and thus are not the target for correction.

<<Summary of Change Pattern>>

As described above, it has been found that information regarding deviation in tracking is included in a change pattern repeatedly occurring in temporal change in generated power. When there is no indication (the pattern (a)) of tracking deviation in the change pattern, tracking is being performed normally. Moreover, by comparing the detected change pattern with a form (the pattern (b)) characteristic to deviation in the elevation and a form (the pattern (c)) characteristic to deviation in the azimuth, the presence/absence of tracking deviation can be detected.

Moreover, by the comparison, based on similarity of the form of the change pattern, among the two axes of the azimuth and the elevation, an axis in which the deviation is occurring can be identified. Then, an angle in the identified axis is corrected, whereby the tracking deviation can be eliminated. As a specific technique of the comparison, for example, the cycle of change in which a large magnitude of change exceeding a threshold value is occurring is detected, and this cycle is compared with a time period necessary for the sun to move, from that time, by a constant angle in the elevation direction or the azimuth direction, whereby the determination can be performed.

As described above, based on the change pattern of generated power, it is possible to detect the presence/absence of tracking deviation, to identify the axis (azimuth/elevation) in which the tracking deviation is occurring, and to know the directionality of the change, i.e., the sign of the angle to be corrected, based on whether a sawtooth-like change pattern included in the change pattern is (a) a pattern increasing gradually and decreasing at the time of stepped change, or (b) a pattern decreasing gradually and increasing at the time of stepped change. However, for performing appropriate correction, it is preferable to further know the absolute value (correction amount) of the angle to be corrected.

<<Correction Amount Determination Method 1>>

Here, a correction amount determination method 1 in the case of the pattern (b) or (c) will be described. In the case of the pattern (b) or (c), i.e., in the case where the deviation in tracking is in either one of the elevation and the azimuth, by measuring temporal change in generated power with either one of the elevation and the azimuth fixed, deviation in the other angle corresponding to generated power reduced relative to generated power without deviation can be examined, in advance. Thus, by forcedly creating tracking deviation, deviation in the angle corresponding to the reduced generated power can be easily examined.

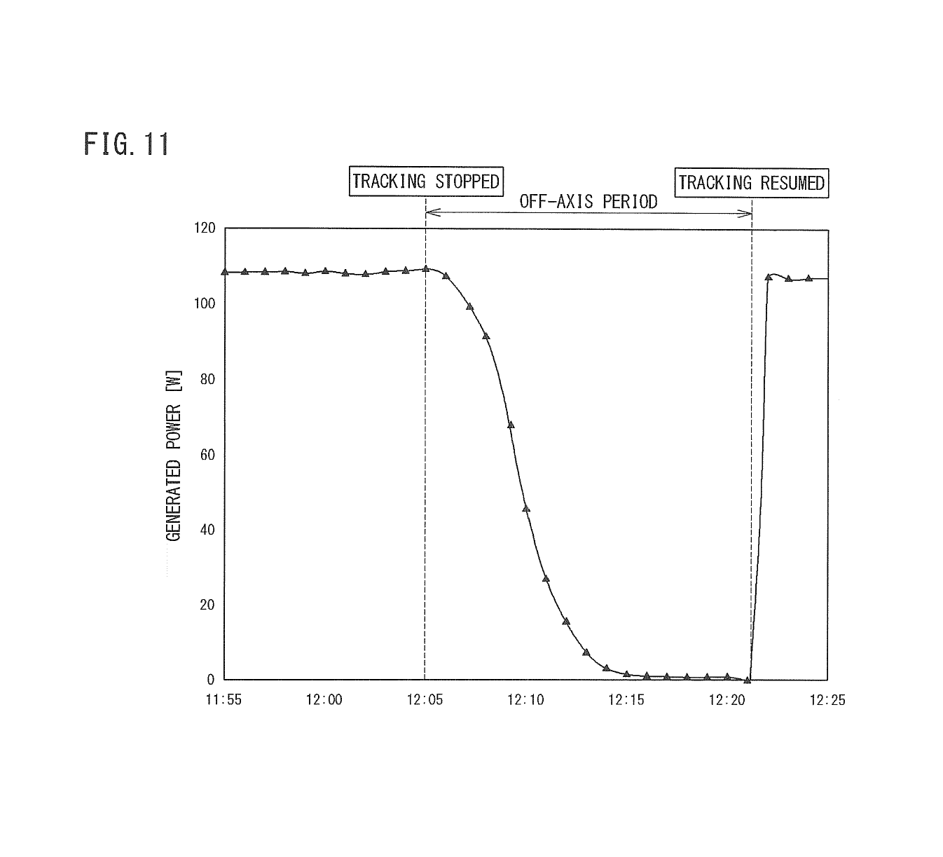

For example, FIG. 11 is a graph of examination, with respect to one module, for example, of how generated power is reduced in a period (OFF-AXIS period) from when tracking is stopped around the culmination time where the elevation scarcely changes till tracking is resumed. Upon stop of tracking (time 12:05), tracking deviation in the azimuth gradually increases, and accordingly, generated power is reduced. Thus, by conducting such an experiment in advance, back data (correction amount derivation data) indicating correspondence relationship between reduction of generated power and deviation amount in the azimuth can be obtained.

Table 1 below is one example of back data indicating relationship between deviation amount D in angle and generated power ratio RA.

TABLE 1

| Deviation | Generated |
|---|---|
| amount | power ratio |
| D [degree] | RA [%] |
| 0.00 | 100.0 |
| 0.35 | 97.4 |
| 0.71 | 90.9 |
| 1.06 | 81.1 |
| 1.42 | 63.3 |
| 1.77 | 41.2 |
| 2.12 | 24.7 |
| 2.48 | 12.8 |
| 2.83 | 5.8 |
| 3.18 | 2.5 |

The generated power ratio above is obtained after normalization by solar irradiance has been performed. RA is (generated power when there is a deviation amount)/(power generation amount when the deviation amount is 0). In a case where the Fresnel lens and the power generating element are both square, the relationship of the generated power ratio RA relative to the deviation amount D is the same for both the elevation and the azimuth, and thus, the same data can be used for determination of a correction amount. When the relationship is not the same, it is sufficient to prepare such data for each of the elevation and the azimuth.

The deviation amount when the tracking pedestal has been driven in a stepped manner (driven by the stepping motor) and the generated power ratio before and after the drive are as in Table 2 below, for example.

TABLE 2

| | Change of deviation | Generated power |
|---|---|---|
| Deviation | amount at stepped | ratio RB before |
| amount | drive of tracking | and after drive |
| D[degree] | pedestal | [%] |
| 0.18 | 0.00 [symbol] 0.35 | 98.7 |
| 0.53 | 0.35 [symbol] 0.71 | 96.5 |
| 0.89 | 0.71 [symbol] 1.06 | 94.3 |
| 1.24 | 1.06 [symbol] 1.42 | 87.7 |
| 1.59 | 1.42 [symbol] 1.77 | 78.8 |
| 1.95 | 1.77 [symbol] 2.12 | 75.0 |
| 2.30 | 2.12 [symbol] 2.48 | 68.4 |
| 2.65 | 2.48 [symbol] 2.83 | 62.5 |
| 3.00 | 2.83 [symbol] 3.18 | 59.3 |

The generated power ratio above is obtained after normalization by solar irradiance has been performed. In this example, the stepped drive angle is about 0.35 degrees. In a case where generated power decreases as a result of the stepped drive,

RB=(power generation amount after stepped drive)/(power generation amount before stepped drive).

In a case where generated power increases as a result of the stepped drive,

RB=(power generation amount before stepped drive)/(power generation amount after stepped drive).

In a case where the Fresnel lens and the power generating element are both square, the relationship of the generated power ratio RB relative to the deviation amount D is the same for both the elevation and the azimuth, and thus, the same data can be used for determination of a correction amount. When the relationship is not the same, it is sufficient to prepare such data for each of the elevation and the azimuth.

By utilizing such data, based on generated power reduced relative to generated power without deviation, when tracking deviation has occurred, the absolute value of the angle to be corrected can be determined. Strictly speaking, in the example in FIG. 11, reduction of generated power due to deviation in the elevation is also included, but it is considerably small compared with the deviation in the azimuth and thus is ignored. However, in order to further increase the accuracy, for example, if only tracking in the azimuth is stopped and tracking in the elevation is continued, reduction of generated power due to deviation in the azimuth only can be examined in advance.

In reserve, if only tracking in the elevation is stopped and tracking in the azimuth is continued, reduction of generated power due to deviation in the elevation only can be examined. This method may be applied to a case of the pattern (d), but when the extent of the mixture of azimuth deviation and elevation deviation is large, large errors are caused, and thus, the method described below may be applied.

<<Correction Amount Determination Method 2>>

Next, a correction amount determination method 2 applicable to any case of the pattern (b), (c), and (d) will be described. That is, this method can be applied not only to a case where deviation in tracking in only either one of the azimuth/elevation is occurring, but also to a case where deviation in tracking in the azimuth and deviation in tracking in the elevation are mixed. First, from a state where deviation is present neither in the azimuth nor in the elevation, rotational operation in the azimuth is caused by, for example, 0.1 degrees being the minimum rotation angle by the stepping motor, and then, a change ratio of generated power before and after the operation is recorded. Next, for example, from a state where the azimuth is deviated by Δθ, rotational operation in the azimuth is caused by 0.1 degrees by the stepping motor, and a change ratio of generated power before and after the operation is recorded. Such records are taken up to a predetermined angle (the maximum deviation angle anticipated), whereby back data (correction amount derivation data) is prepared in advance. In other words, this is to examine the change ratio (slope) of generated power relative to a unit rotation angle by the stepping motor, the change ratio corresponding to deviation in tracking. The larger deviation in tracking becomes, the larger the change ratio becomes. Therefore, if the change ratio is detected, the absolute value of the deviation angle is known. Also with regard to the elevation direction, back data (correction amount derivation data) is prepared in advance in the same manner.

Based on the back data (correction amount derivation data), when the actual change in generated power corresponding to rotational operation by, for example, 0.1 degrees in the azimuth is checked against the back data (correction amount derivation data) regarding the azimuth, it is clarified how many degrees the deviation in the azimuth is. Similarly, when the actual change in generated power corresponding to rotational operation by 0.1 degrees in the elevation is checked against the back data (correction amount derivation data) regarding the elevation, it is clarified how many degrees the deviation in the elevation is. If there is no deviation in tracking, the change in generated power falls within a very small range. The correction amount determination method 2 above has advantage of applicability to any of the patterns (b), (c), and (d).

<<One Example of Correction Result>>

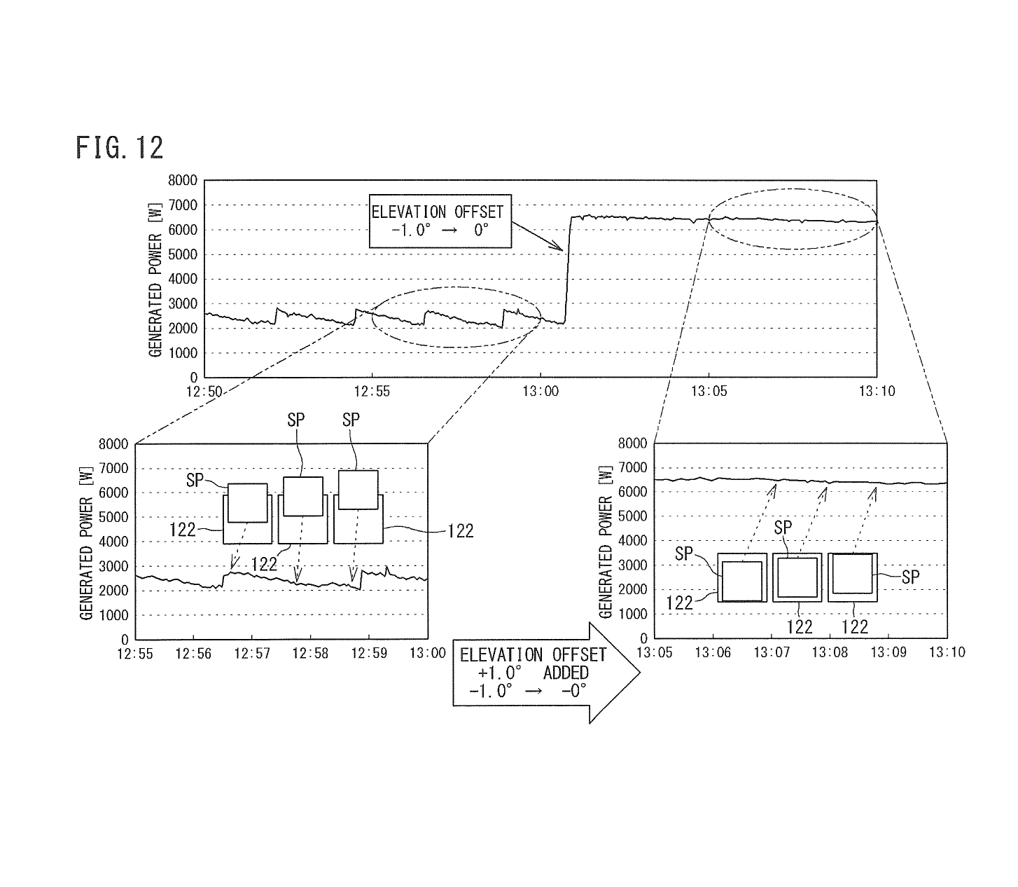

FIG. 12 shows, as one example, a case where the elevation has been corrected from, for example, the state of the pattern (b). The graphs on the lower side in the drawing show partially enlarged portions of the graph on the upper side. In addition, as in FIG. 8, positions where the concentration spot SP is formed on the power generating element 122 are shown.

Here, when correction of adding +1.0 degree as an offset value has been performed, the elevation having been −1.0 degree becomes 0 degrees. Accordingly, after the correction, the change pattern due to the deviation in the elevation is eliminated, and generated power increases.

<<Example as Concentrator Photovoltaic System>>

Next, Example of a concentrator photovoltaic system (including description of a method for detecting or a method for correcting tracking deviation) viewed in terms of tracking operation will be descried. It should be noted that description here is about “a concentrator photovoltaic system viewed in terms of tracking operation”, and thus, illustration and description of an output control section (for example, an MPPT control section, an inverter circuit section, and the like) supposed to be included in a power generating system are omitted.

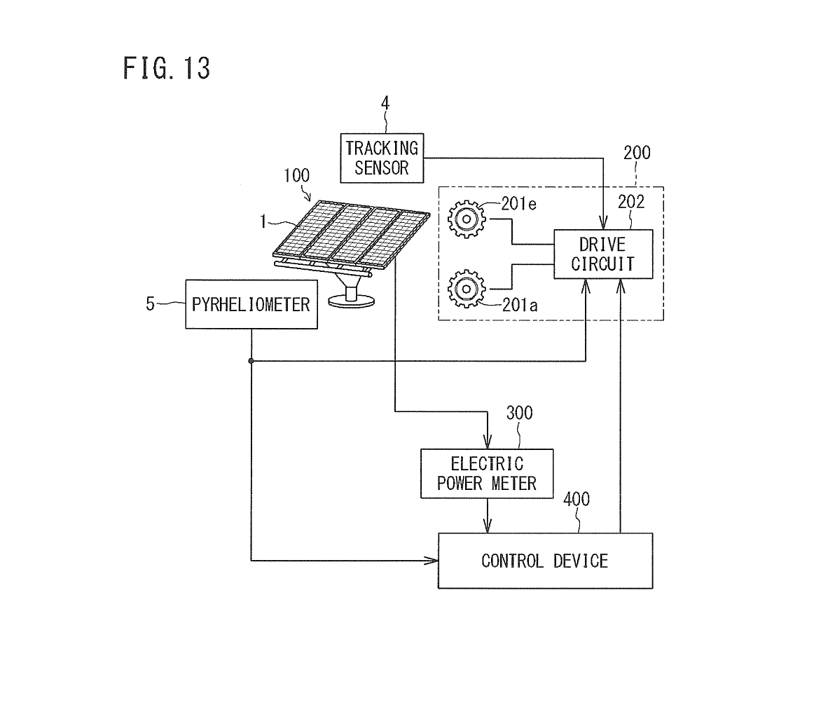

FIG. 13 shows one example of a concentrator photovoltaic system viewed in terms of the tracking operation. In the figure, as described above, the concentrator photovoltaic apparatus 100 includes a driving device 200 for operation of tracking the sun, on the rear surface side thereof, for example. The driving device 200 includes a stepping motor 201e for driving into the elevation direction, a stepping motor 201 a for driving into the azimuth direction, and a drive circuit 202 which drives these. It should be noted that the stepping motors are merely examples, and another power source may be used.

The concentrator photovoltaic apparatus 100 is provided with the tracking sensor 4 and the pyrheliometer 5, by utilizing vacant space of the concentrator photovoltaic panel 1 or in the vicinity thereof. An output signal (direct solar irradiance) from the pyrheliometer 5 is inputted to the drive circuit 202 and a control device 400. Generated power of the concentrator photovoltaic panel 1 can be detected by an electric power meter 300, and a signal indicating the detected electric power is inputted to the control device 400. The driving device 200 stores the latitude and the longitude of the installation place of the concentrator photovoltaic panel 1, and also has a function of a clock. Based on an output signal from the tracking sensor 4 and the position of the sun calculated from the latitude, the longitude, and the time, the driving device 200 performs tracking operation such that the concentrator photovoltaic panel 1 always faces the sun. However, as mentioned above, there are cases where the tracking sensor 4 is not provided. In such a case, tracking operation is performed based on only the position of the sun calculated from the latitude, the longitude, and the time.

<<One Example of Correction Process by Software>>

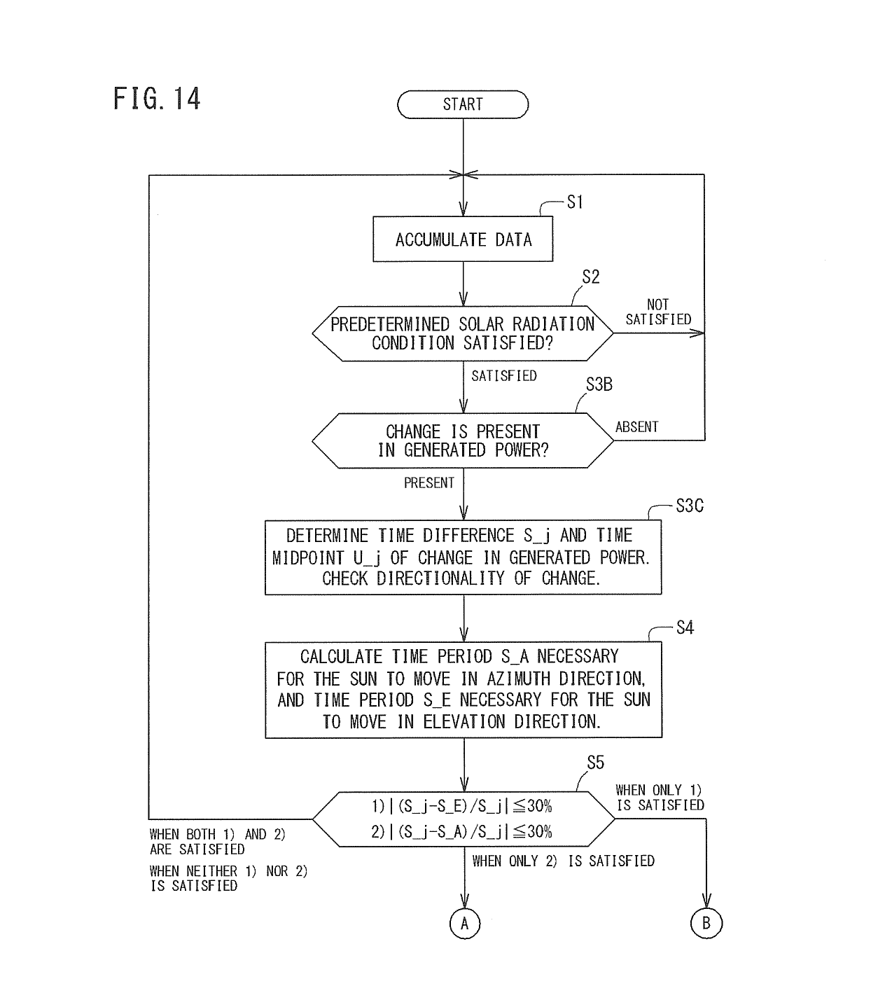

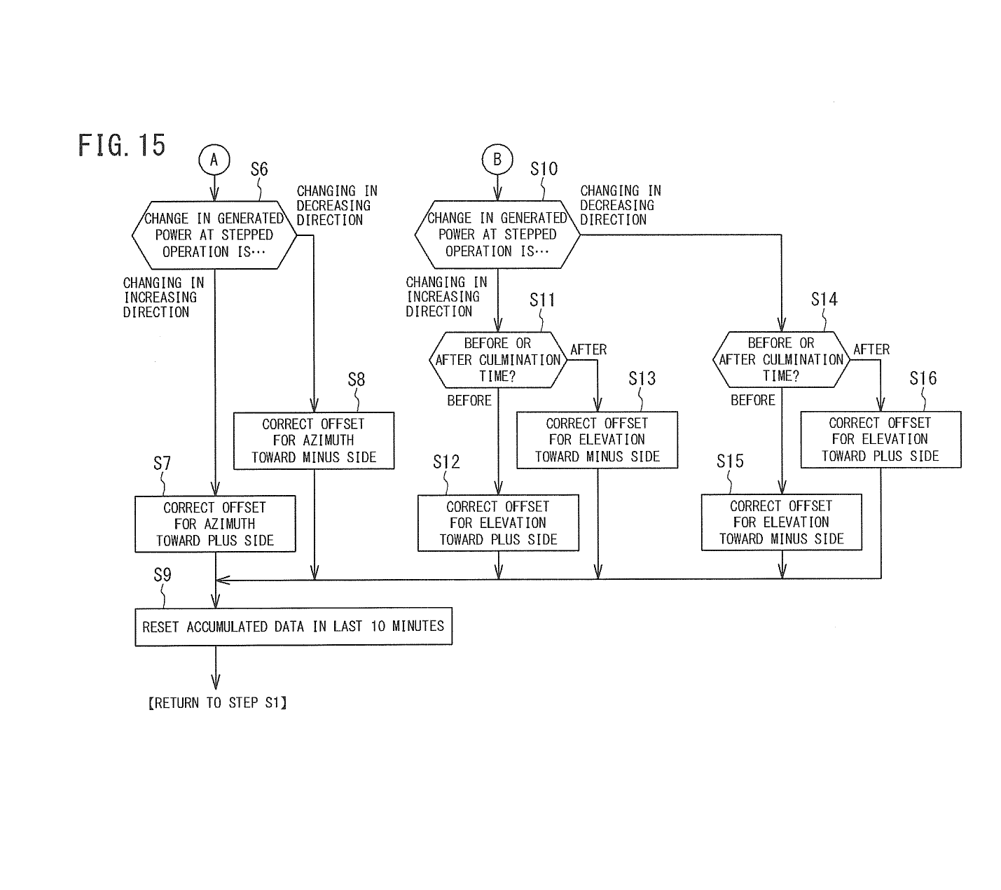

FIG. 14 and FIG. 15 show a flow chart of a process regarding detection and correction of tracking deviation, to be executed by the control device 400. A and B at the bottom of FIG. 14 are continued to A and B in FIG. 15, respectively. Numerical values in the flow chart below are merely examples, and the values are not limited thereto.

First, in FIG. 14, upon start of the process, the control device 400 accumulates data at a 5-second interval (step S1). This data is direct solar irradiance, generated power, and time.

Next, the control device 400 determines whether a predetermined solar radiation condition is satisfied (step S2). The predetermined solar radiation condition is determination of whether two conditions, i.e., direct solar irradiance in last 10 minutes being not less than 600 W/m² and the change thereof being within 10%, are both satisfied. That is, the two conditions mean that it is a stable clear sky (being clear). When the predetermined condition is not satisfied, the control device 400 returns the process to accumulation of data (step S1) and waits for the predetermined condition to be satisfied.

When the predetermined condition has been satisfied in step S2, the control device 400 checks the change pattern of generated power (step S3B). That is, the control device 400 checks, with respect to generated power in last 10 minutes, the presence/absence of change in generated power, in which the difference in generated power at consecutive measurements becomes a difference not less than 10% of generated power (i.e., not within the range of normal fluctuation) even after normalization regarding change in direct solar irradiance has been performed.

If there is no such step-like change (for example, such a case as of the pattern (a) in FIG. 6), the control device 400 determines that correction is not necessary, and returns the process to step S1. It should be noted that, between step S2 and step S3B, it is possible to insert a step (step S3A (not shown)) of determining as normal if there is a value not less than 95% of generated power in the normal state after normalization regarding change in direct solar irradiance has been performed, and then returning the process to step S1. Furthermore, at any of the operations of returning the process to step S1, instead of returning the process to step S1, but determining as being normal, the control process may be stopped once. However, for the purpose of continuing monitoring work in order to always maintain a good state, it is preferable to return the process to step S1.

Next, with respect to generated power in last 10 minutes, in a case where there are step-like changes in generated power, in which the difference in generated power at consecutive measurements becomes a difference not less than 10% even after normalization regarding change in direct solar irradiance has been performed, an occurrence cycle (S_j) of the step-like changes and a time midpoint (U_j) thereof are determined, and further, the directionality of the change is checked (step S3C). That is, the sign of the angle to be corrected is known based on whether the sawtooth-like change pattern included in the change pattern is (a) a pattern increasing gradually and decreasing at the time of stepped change, or (b) a pattern decreasing gradually and increasing at the time of stepped change.

For example, with respect to generated power in last 10 minutes, regarding the difference in generated power at consecutive measurements, the amounts of step-like changes in generated power at points showing difference of not less than 10% even after normalization regarding change in direct solar irradiance has been performed are assumed as dP1, dP2, . . . , dPn, and the times before and after their corresponding stepped changes are assumed as T_{1A}, T_{1B}, T_{2A}, T_{2B} . . . , T_{nA}, and T_{nB}. Here, an integer from 1 to (n−1) is assumed as m, and the difference in the occurrence times of these changes is expressed as Sm=T_{(m+1)A}−T_{mA}. Moreover, the time midpoint is expressed as Um=(T_{(m+1)A}+T_{mA})/2. Then, it is sufficient to select representative occurrence cycle (S_j) and time midpoint (U_j) from these sets of Sm and Um. As a method for selecting m, (A) m at the time of dPm being maximum, (B) m of the most recent Um, (C) m at the time of dPm being the central value in the distribution, or the like is conceivable, and any of them may be employed. In order to realize a low cost circuit by reducing the load of the calculation process, (B) is preferable. Further, the directionality of change is determined based on the relationship of the magnitude of generated power at T_{mA} and T_{mB}.

Here, as in the pattern (d) in FIG. 6, in a case where azimuth deviation and elevation deviation are mixed, two types of the dPm group will appear, and S_j and U_j corresponding to each type may be determined. As a method for processing by software, for example, the following method can be employed. However, this is merely one example and the numerical values are also merely examples. For example, a dPm group is found in which, in a constant time period, the difference in generated power at consecutive measurements becomes a difference not less than 10% of generated power, and each amount of difference among the differences is within a range of ±10%, and this appears cyclically. In other words, a set of dPms having similar values is found. Then, the cycle Sm of the time Tm corresponding to each dPm is read. Further, its corresponding time midpoint Um is read. Furthermore, the directionality of the change is also determined. Accordingly, the cycle S_j of the change and the time midpoint U_j caused by deviation in, for example, the azimuth are obtained, and also the directionality of the change is also known.

When there are two types of the dPm group (i.e., there is another group in which the magnitude of change is different from that of the above dPm group by not less than 20%, for example), a similar process is performed also on the second type, i.e., the change caused by deviation in the elevation, for example. Then, it is determined that this is a mixed pattern like the pattern (d). If there are three types, as for the third type, the process is not performed, or the process is returned to the start. When there are two types of the dPm group and corresponding two types of S_j, U_j, and directionality of change are obtained, it is sufficient that either one type of them is selected, and then, the process is advanced to the next step to correct the angle deviation of the selected type, first.

Then, in the next step S4, the control device 400 calculates a time period S_A necessary for the sun, from the time midpoint U_j, to move in the azimuth direction by an amount corresponding to the minimum movement angle by the stepping motor 201a in the azimuth direction, and a time period S_E necessary for the sun, from the time midpoint U_j, to move in the elevation direction by an amount corresponding to the minimum movement angle by the stepping motor 201e in the elevation direction, based on the time U_j, and the latitude and the longitude of the installation place of the concentrator photovoltaic panel 1 and the driving device 200. It should be noted that these time periods may be detected by the tracking sensor.

Next, the control device 400 determines whether the relationship of 1) and 2) below are satisfied (step S5).

|(S_{—}j−S_{—}E)/S_{—}j|≦30% 1)

|(S_{—}j−S_{—}A)/S_{—}j|≦30% 2)

1) above is a condition for grasping a state similar to the response (the pattern (b) in FIG. 6) of generated power when there is deviation in the elevation. 2) is a condition for grasping a state similar to the response (the pattern (c) in FIG. 6) of generated power when there is deviation in the azimuth.

When only 1) is satisfied, it is possible to determine that there is deviation in the elevation. When only 2) is satisfied, it is possible to determine that there is deviation in the azimuth. When both 1) and 2) are satisfied (in such a case where the values of S_E and S_A are close to each other depending on the time zone), and when neither of 1) nor 2) is satisfied, the control device 400 determines that making determination is difficult or correction is not necessary, and returns the process to step S1.

When only 2) above is satisfied, the control device 400 advances the process to step S6 in FIG. 15, and determines the direction of correction, depending on whether the change at the step-like change in generated power is in an increasing direction or in a decreasing direction. In the case of the change in the increasing direction, the control device 400 corrects the offset for the azimuth toward the plus side to correct the tracking deviation causing the change in generated power (step S7). In the case of the change in the decreasing direction, the control device 400 corrects the offset for the azimuth toward the minus side to correct the tracking deviation causing the change in generated power (step S8).

On the other hand, only 1) above is satisfied, the control device 400 advances the process to step S10 in FIG. 15, and determines whether the change at the step-like change in generated power is in the increasing direction or in the decreasing direction. In the case of the change in the increasing direction, the control device 400 further determines whether it is before or after the culmination time (step S11). When it is before the culmination time, the control device 400 corrects the offset for the elevation toward the plus side, to correct the tracking deviation causing the change in generated power (step S12). When it is after the culmination time, the control device 400 corrects the offset for the elevation toward the minus side, to correct the tracking deviation causing the change in generated power (step S13).

Moreover, when the change at the step-like change in generated power is in the decreasing direction in step S10, the control device 400 further determines whether it is before or after the culmination time (step S14). When it is before the culmination time, the control device 400 corrects the offset for the elevation toward the minus side, to correct the tracking deviation causing the change in generated power (step S15). When it is after the culmination time, the control device 400 corrects the offset for the elevation toward the plus side, to correct the tracking deviation causing the change in generated power (step S16). As a method for deriving a correction amount, any of the methods described in <<Correction amount determination method 1>> and <<Correction amount determination method 2>> above may be used. Alternatively, with the correction amount set to an appropriate fixed value, the correction routine may be repeated to realize convergence to a state free of deviation.

Upon completion of any of the correction in step S7, S8, S12, S13, S15, and S16, the control device 400 resets the accumulated data in the last 10 minutes to end the series of processes (step S9), and returns the process to step S1 again.

In the above, in step S4 and thereafter, a case of handling one type of the set of S_j, U_j, and directionality of change has been described. However, in step S3C, when it has been determined as a mixed pattern, the process may be first advanced with regard to one type of S_j, U_j, and directionality of change, and then, the processes of step S4 and thereafter may be successively performed also with regard to the other type, before the process is returned to step S1.

If the concentrator photovoltaic apparatus 100 is used in a state where always no deviation in tracking occurs as a result of periodical execution (for example, everyday) of the processes shown in FIG. 14 and FIG. 15, the device 100 can obtain the maximum electric power that can be obtained under the given environment.

<<Others>>

In the above embodiment, it has been shown that the presence/absence of deviation in tracking can be detected by comparing, for example, around the culmination time of the sun, the change pattern repeatedly occurring in temporal change in generated power with a form characteristic to the deviation in the azimuth and a form characteristic to the deviation in the elevation. However, depending on the time, the form characteristic to the deviation in the azimuth and the form characteristic to the deviation in the elevation change. Thus, in the case of a time not around the culmination time, it is necessary to perform detection and correction, taking the time into consideration.

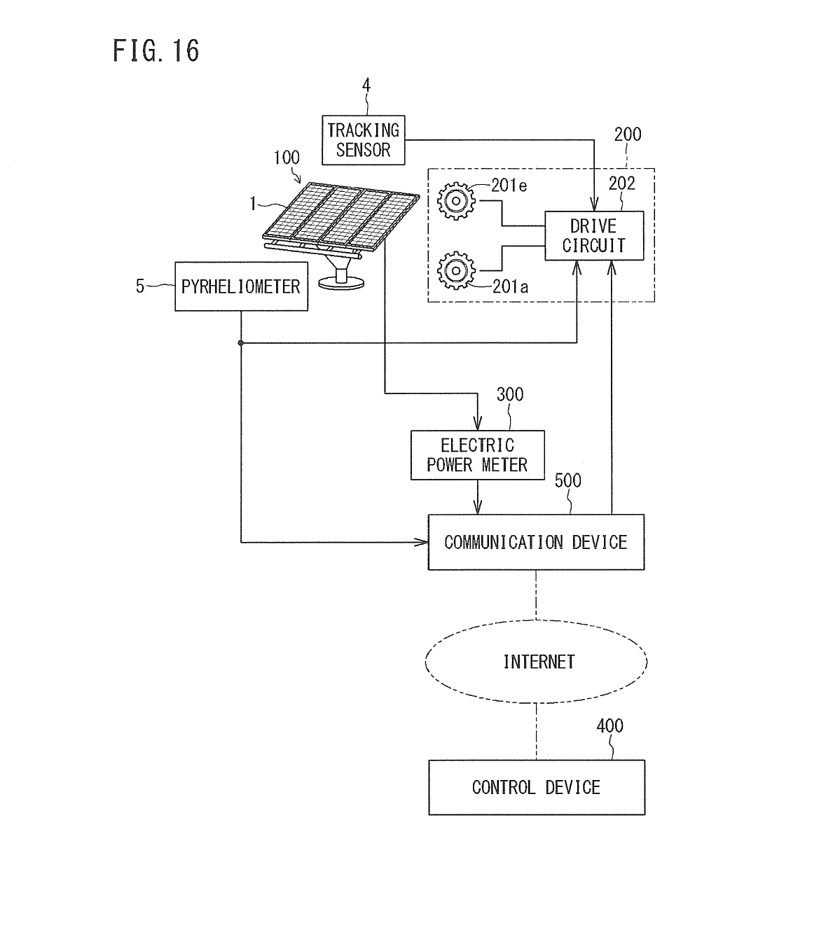

FIG. 16 shows another example of the concentrator photovoltaic system viewed in terms of tracking operation. The difference from FIG. 13 is that a communication device 500 is provided at the site where the concentrator photovoltaic apparatus 100 is installed, and the control device 400 is installed at a remote site via a communication line such as the Internet. The communication device 500 transmits a measurement signal of the electric power meter 300 to the control device 400, and receives, from the control device 400, a correction signal to the driving device 200.

In this case, deviation in tracking can be corrected by remote control via the communication line, and thus, the configuration is preferable for centralized management from a distant place.

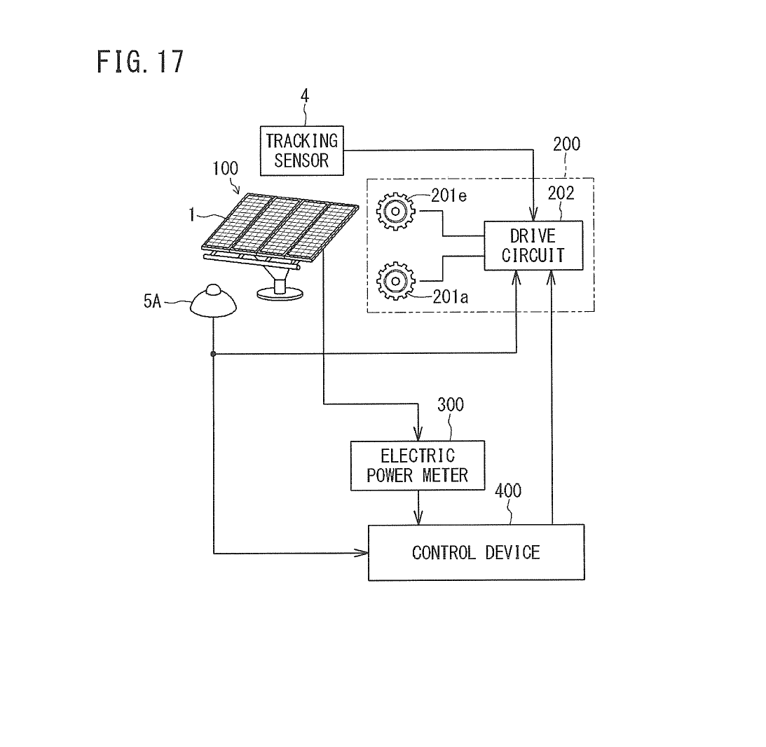

FIG. 17 shows still another example of the concentrator photovoltaic system. The difference from FIG. 13 is that, instead of the pyrheliometer 5 (FIG. 13), a pyranometer 5A is employed.

The pyranometer includes, for example, a horizontal pyranometer and a normal pyranometer. The horizontal pyranometer is not installed integrally with the concentrator photovoltaic panel 1, and is fixedly installed in the vicinity of the concentrator photovoltaic panel 1, for example. The horizontal pyranometer does not perform operation of tracking the sun. On the other hand, the normal pyranometer measures global light (direct light and diffuse light) received at a normal plane, and performs operation of tracking the sun, similarly to the concentrator photovoltaic panel 1. The normal pyranometer is installed on the concentrator photovoltaic panel 1 and performs tracking operation together with the concentrator photovoltaic panel 1, or installed in the vicinity of the concentrator photovoltaic panel 1 and performs tracking operation by itself

With regard to the process of step S2 in FIG. 14 when the pyranometer 5A is used, in the case of the normal pyranometer, when the normal global solar irradiance detected by the normal pyranometer is not less than a predetermined value, the predetermined solar radiation condition is satisfied. In the case of the horizontal pyranometer, when the horizontal global solar irradiance detected by the horizontal pyranometer is not less than a predetermined value, the predetermined solar radiation condition is satisfied. Then, only when the solar radiation condition is satisfied, detection and correction of deviation in tracking are performed.

Compared with the pyrheliometer, the normal pyranometer or the horizontal pyranometer is less likely to be affected by dirt on a window portion of a built-in solar radiation sensor. Moreover, the normal pyranometer or the horizontal pyranometer has fewer problems of tracking deviation causing measurement error in the case of the pyrheliometer. Thus, with regard to actual intensity measurement of sunlight, there are cases where more accurate information can be obtained.

It should be noted that the control device 400 (FIG. 13, FIG. 16) may include a computer and software, or may be configured mainly by hardware.

Briefly, a program causing a computer to realize functions is a program to be used in a concentrator photovoltaic system, the program causing the computer to realize (i) a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking; and (ii) a function of, when the deviation of tracking is present, identifying, among two axes of the azimuth and the elevation, an axis in which the deviation is occurring, and instructing the driving device to correct an angle in the identified axis.

It is a program for detecting tracking deviation that realizes (i) above by means of a computer, and it is a program for correcting tracking deviation that realizes (i) and (ii) by means of a computer. Since necessary functions are put into programs, production of the concentrator photovoltaic system is easy, addition to an existing concentrator photovoltaic system is also easy, and version up of the system is also easy.

Similarly, the control device 400 when configured mainly by hardware is the control device 400 having at least the function of (i) or the functions of (i) and (ii) as hardware. A part or the whole of the control device 400 of this case may be realized as a semiconductor integrated circuit, for example, a one-chip IC. In this case, necessary functions are installed in the one-chip IC, and thus, production of the concentrator photovoltaic system is facilitated. Moreover, the semiconductor integrated circuit can be produced at a low cost.

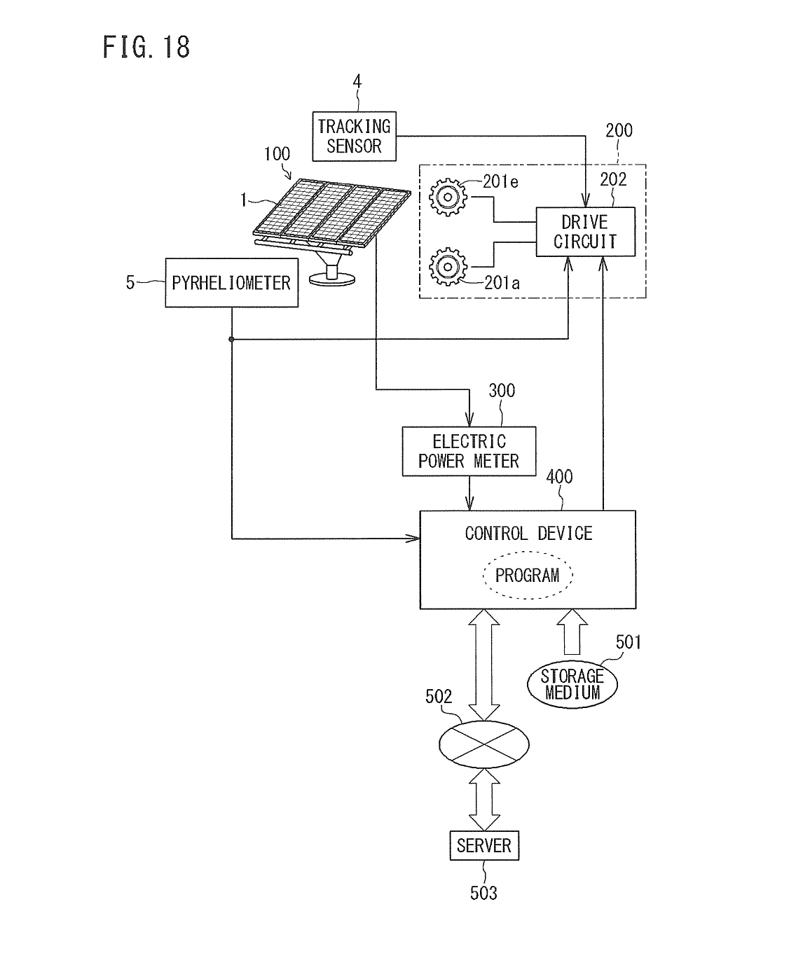

FIG. 18 shows another example of the concentrator photovoltaic system. The difference from FIG. 13 is that, as the control device 400, a commercially-available computer is used, for example. In this case, the functions of the control device 400 are provided as a program stored in a computer-readable storage medium (storage medium) 501, and are installed in the control device 400 being a computer. Accordingly, the control device 400 can exhibit necessary functions. As the storage medium, for example, an optical disk, a magnetic disk, a compact memory, or the like is preferable. The program is stored in the storage medium 501 and can be distributed as the storage medium 501.

Further, download of the program via a communication line 502 such as the Internet, or a form of using the program via an ASP (Application Service Provider) from a server 503 is also possible.

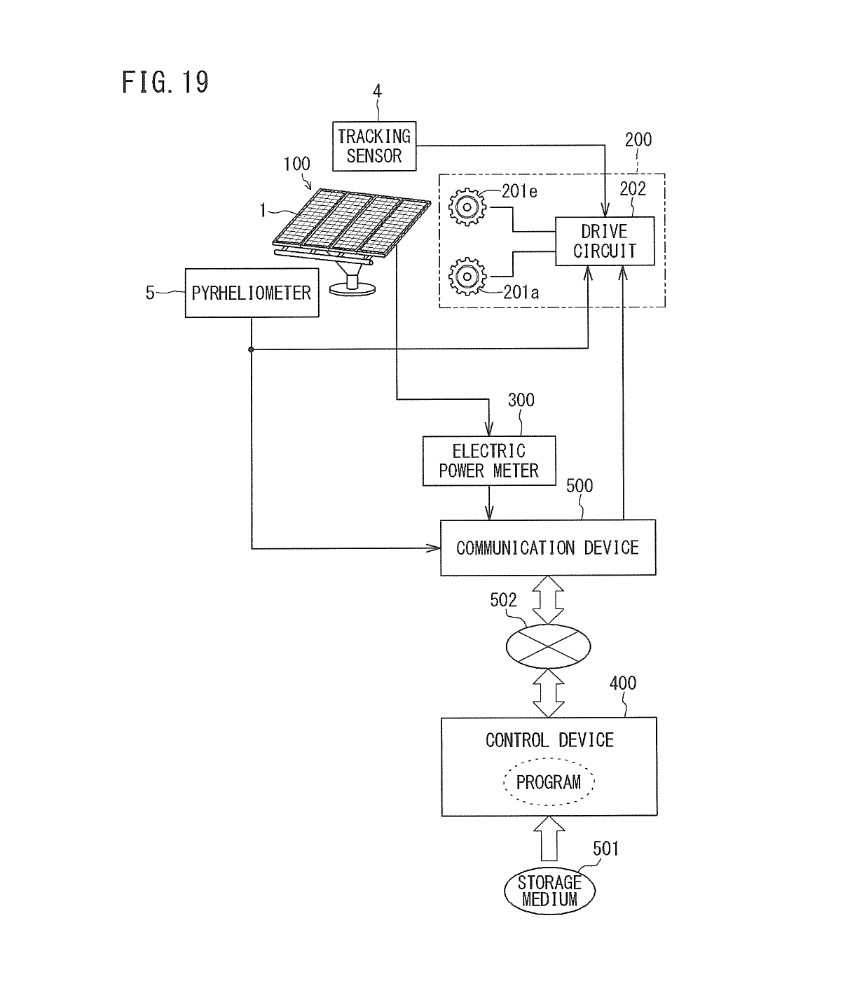

FIG. 19 shows still another example of the concentrator photovoltaic system. The difference from FIG. 16 is that, as the control device 400, a commercially-available computer is used, for example. In this case, the functions of the control device 400 are provided as a program stored in the computer-readable storage medium (storage medium) 501, and are installed in the control device 400 being a computer. Accordingly, the control device 400 can exhibit necessary functions. As the storage medium, for example, an optical disk, a magnetic disk, a compact memory, or the like is preferable.

It should be noted that the control devices 400 in FIG. 13, FIG. 16, FIG. 18, and FIG. 19 can be combined (used in parallel) with each other.

Also in FIG. 18 and FIG. 19, as in FIG. 17, instead of the pyrheliometer, the pyranometer can be used.

It should be understood that the embodiments disclosed herein are merely illustrative and not restrictive in all aspects. The scope of the present invention is defined by the scope of the claims, and is intended to include meaning equivalent to the scope of the claims and all modifications within the scope.

### REFERENCE SIGNS LIST

1 concentrator photovoltaic panel
1M concentrator photovoltaic module
3 pedestal
3a post
3b base
4 tracking sensor
5 pyrheliometer
5A pyranometer
11 housing
11a bottom surface
11b flange portion
12 flexible printed circuit
13 primary concentrating portion
13f Fresnel lens
14 connector
100 concentrator photovoltaic apparatus
121 flexible substrate
122 power generating element
123 secondary concentrating portion
200 driving device
201a stepping motor
201e stepping motor
202 drive circuit
300 electric power meter
400 control device
500 communication device
501 storage medium
502 communication line
503 server
SP concentration spot

1. A concentrator photovoltaic system comprising:
a concentrator photovoltaic panel;
a driving device configured to cause the concentrator photovoltaic panel to perform operation of tracking the sun; and
a control device configured to detect a change pattern repeatedly occurring in temporal change in generated power of the concentrator photovoltaic panel, and configured to compare the detected change pattern with a form characteristic to deviation in an azimuth and a form characteristic to deviation in an elevation, to detect the presence/absence of deviation in tracking.

2. The concentrator photovoltaic system according to claim 1, wherein when the deviation in tracking is present, the control device identifies, among two axes of the azimuth and the elevation, an axis in which the deviation is occurring, and instructs the driving device to correct an angle in the identified axis.

3. The concentrator photovoltaic system according to claim 2, wherein the control device determines a sign of the angle to be corrected, based on whether a sawtooth-like change pattern included in the change pattern is
(a) a pattern increasing gradually and decreasing at a time of stepped change, or
(b) a pattern decreasing gradually and increasing at a time of stepped change.

4. The concentrator photovoltaic system according to claim 2, wherein the control device determines an absolute value of the angle to be corrected, based on generated power reduced relative to generated power without deviation, stored in advance.

5. The concentrator photovoltaic system according to claim 2, wherein the control device determines an absolute value of the angle to be corrected, based on a change ratio of generated power corresponding to tracking operation.

6. The concentrator photovoltaic system according to claim 2, wherein the concentrator photovoltaic panel includes a pyrheliometer, and only when a direct solar irradiance detected by the pyrheliometer is not less than a predetermined value, the control device performs the correction.

7. The concentrator photovoltaic system according to claim 2, wherein the control device performs the correction in a time zone where the sun culminates.

8. The concentrator photovoltaic system according to claim 2, wherein as a pyranometer, a normal pyranometer or a horizontal pyranometer is provided, and in a case of the normal pyranometer, when a normal global solar irradiance detected by the normal pyranometer is not less than a predetermined value, the correction is performed, and in a case of the horizontal pyranometer, only when a horizontal global solar irradiance detected by the horizontal pyranometer is not less than a predetermined value, the correction is performed.

9. The concentrator photovoltaic system according to claim 2, further comprising a communication device configured to transmit a measurement signal of an electric power meter measuring the generated power, and configured to receive a correction signal to the driving device, wherein the control device is installed in a place distanced from the concentrator photovoltaic panel and the driving device, and performs communication with the communication device via a communication line to receive the measurement signal and transmit the correction signal.

10. A method for detecting tracking deviation in a concentrator photovoltaic apparatus including a driving device configured to cause a concentrator photovoltaic panel to perform operation of tracking the sun, the method comprising:
detecting a change pattern included in temporal change in generated power of the concentrator photovoltaic panel; and
comparing the detected change pattern with a form characteristic to deviation in an azimuth and a form characteristic to deviation in an elevation, to detect the presence/absence of deviation in tracking.

11. A method for correcting tracking deviation, the method being executed, in a concentrator photovoltaic apparatus including a driving device configured to cause a concentrator photovoltaic panel to perform operation of tracking the sun, by a control device configured to detect generated power of the concentrator photovoltaic panel and to control the driving device, the method comprising:
detecting a change pattern included in temporal change in generated power of the concentrator photovoltaic panel;
comparing the detected change pattern with a form characteristic to deviation in an azimuth and a form characteristic to deviation in an elevation, to detect the presence/absence of deviation in tracking;
identifying, when the deviation is present, among two axes of the azimuth and the elevation, an axis in which the deviation is occurring; and
instructing the driving device to correct an angle in the identified axis.

12. The method for correcting tracking deviation according to claim 11, wherein by measuring temporal change in generated power with either one of the azimuth and the elevation fixed, deviation in the other angle corresponding to generated power reduced relative to generated power without deviation is examined, in advance.

13. A control device configured to be used in a concentrator photovoltaic system, the concentrator photovoltaic system including a concentrator photovoltaic panel and a driving device configured to cause the concentrator photovoltaic panel to perform operation of tracking the sun, the control device having a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking.

14. The control device according to claim 13 having a function of
identifying, when the deviation in tracking is present, among two axes of the azimuth and the elevation, an axis in which the deviation is occurring, and instructing the driving device to correct an angle in the identified axis.

15. The control device according to claim 13, wherein the function is realized by a semiconductor integrated circuit.

16. A program for detecting tracking deviation to be used in a concentrator photovoltaic system, the concentrator photovoltaic system including a concentrator photovoltaic panel and a driving device configured to cause the concentrator photovoltaic panel to perform operation of tracking the sun, the program causing a computer to realize a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking.

17. A program for correcting tracking deviation to be used in a concentrator photovoltaic system, the concentrator photovoltaic system including a concentrator photovoltaic panel and a driving device configured to cause the concentrator photovoltaic panel to perform operation of tracking the sun, the program causing a computer to realize:
a function of detecting a change pattern repeatedly occurring in temporal change in generated power of the concentrator photovoltaic panel, and comparing the detected change pattern with a form characteristic to deviation in an azimuth and a form characteristic to deviation in an elevation, to detect the presence/absence of deviation in tracking; and
a function of, when the deviation in tracking is present, identifying, among two axes of the azimuth and the elevation, an axis in which the deviation is occurring, and instructing the driving device to correct an angle in the identified axis.

18. The control device according to claim 14, wherein the function is realized by a semiconductor integrated circuit.
